(19) United States
(12) Patent Application Publication
(10) Pub. No.: US 2007/0145435 A1
(43) Pub. Date: Jun. 28, 2007

(54) MOS VARACTOR

(76) Inventor: San Hong Kim, Gyeonggi-do (KR)

Correspondence Address: SHERR & NOURSE, PLLC, 620 HERNDON PARKWAY, SUITE 200, HERNDON, VA, 20170, US

(21) Appl. No.: 11/616,754

(22) Filed: Dec. 27, 2006

(30) Foreign Application Priority Data
Dec. 28, 2005 (KR) 10-2005-0132490

(51) Int. Cl. H01L 29/76

(52) U.S. Cl. 257/288

(57) ABSTRACT

Embodiments relate to a MOS varactor and a method for manufacturing the same, in which an ion implantation process for adjusting a threshold voltage may be omitted so as to lower the surface density of an N type well, thereby expanding a tuning range. The MOS varactor may include a semiconductor substrate having an active area and a field area, in which an isolation layer is formed on the field area, an N type well formed at the active area of the semiconductor substrate, a gate insulating layer and a gate electrode formed at an upper side of the N type well, and an N type impurity area formed in the N type well at both sides of the gate electrode, wherein an impurity surface density of the N type well is in a range of 10¹⁶ atoms/cm³ to 10¹⁷ atoms/cm³.

The present application claims priority under 35 U.S.C. 119 and 35 U.S.C. 365 to Korean Patent Application No. 10-2005-0132490 (filed on Dec. 28, 2005), which is hereby incorporated by reference in its entirety.

### BACKGROUND

Telecommunication devices may use high-frequency integrated circuits, such as a radio frequency (RF) integrated circuit. Such high-frequency integrated circuits may include a varactor, which may have a wide tuning range and a high Q value as a voltage variable capacitor.

The varactor may be called a variable capacitance diode, and may be used to change an oscillation frequency according to a change of a voltage. This may be because the capacitance of a diode (unction capacitance) may be varied when a voltage is inversely applied to the diode.

Since the variation of an oscillation frequency may be large only when the ratio of the maximum capacitance to the minimum capacitance (Cmax/Cmin) is large, varactors having a tuning range capable of maximizing the ratio of maximum capacitance (Cmax)/minimum capacitance (Cmin) may be important.

In certain related art, a process of replacing a gate insulating layer formed between a gate electrode and a bulk (substrate) with a material having a high dielectric constant and a process of using a metal gate to reduce the maximum capacitance in an accumulation state caused by poly gate depletion have been considered. However, such processes may make it difficult to integrate a semiconductor device.

Hereinafter, a method for manufacturing a related art MOS varactor will be described with reference to accompanying drawings.

Referring to FIG. 1A, pad oxide layer (SiO₂) 2 may be formed on semiconductor substrate 1, and nitride layer (SiN) 3 may be deposited on pad oxide layer 2. Then, photoresist layer 4 may be formed on nitride layer 3, and an exposure and development process may be performed with respect to the resultant structure, for example by using a mask defining an active area and a field area. This may selectively remove photoresist layer 4 of the field area.

Referring to FIG. 1B, nitride layer 3, pad oxide layer 2, and semiconductor substrate 1 in the field area may be etched to a prescribed depth, for example by using patterned photoresist layer 4 as a mask. Trench 5 may thereby be formed. Thereafter, photoresist layer 4 may be removed.

Referring to FIG. 1C, insulating layer 7 such as an O₃ TEOS oxide layer may be deposited on a surface (for example, the entire surface) of the semiconductor substrate formed with trench 5. Trench 5 may thus be filled with insulating layer 7.

Referring to FIG. 1D, insulating layer 7, nitride layer 3, and pad oxide layer 2 may be removed, for example through a chemical mechanical polishing (CMP) process. Accordingly a surface of semiconductor substrate 1 may be exposed, and insulating layer 7 may remain in trench 5, thereby forming isolation layer 9.

Referring to FIG. 1E, photoresist layer 10 may be deposited on a surface (for example, the entire surface) of the semiconductor substrate formed with isolation layer 9. Photoresist layer 10 may be patterned through an exposure and development process such that an area for the formation of a varactor may be exposed. In addition, an ion implantation process for adjusting a threshold voltage (Vetch) may be performed by using photoresist layer 10 as a mask.

In the implantation process, arsenic (As) ions or phosphorus (P) ions may be implanted into the surface of semiconductor substrate 1 at the density of approximately 10¹³ atoms/cm². For example, arsenic (As) ions may be implanted with energy of about 150 KeV, and phosphorus (P) ions may be implanted with energy of 100 KeV or less.

Referring to FIG. 1F, if the ion implantation process for adjusting a threshold voltage (Vth) is completed, a punch stop ion implantation process may be performed. The punch stop ion implantation may be more deeply performed as compared with the ion implantation for adjusting a threshold voltage. For example, phosphorus (P) ions may be implanted with energy of 200 KeV or less. A density of ions in the punch stop ion implantation process may be identical to a density of ions in the ion implantation process for adjusting a threshold voltage.

Referring to FIG. 1G, if the punch stop ion implantation process is completed, a channel stop ion implantation process may be performed. The channel stop ions may be implanted to a depth corresponding to the depth of the isolation layer. For example, phosphorus (P) ions may be implanted with energy of 300 KeV or less. The density of ions in the channel punch stop ion implantation process may be identical to the density of ions in the ion implantation process for adjusting a threshold voltage.

Referring to FIG. 1H, if the channel stop ion implantation process is completed, an N type well ion implantation process may be performed. The N type well ion implantation may be deeper than the channel stop ion implantation. For example, phosphorus (P) ions may be implanted with energy of 500 KeV or less. A density of ions in the N type well ion implantation process may be identical to a density of ions in the ion implantation process for adjusting a threshold voltage. A diffusion process may also be performed, thereby forming N type well 16.

Referring to FIG. 1I, after removing photoresist layer 10, gate insulating layer 12 and gate electrode 11 may be formed on N type well 16, and low-density N type impurity areas 13 may be formed in N type well 16 at both sides of gate electrode 11, for example by using gate electrode 11 as a mask.

Referring to FIG. 1J, an insulating layer may be deposited on a surface (for example, the entire surface) of semiconductor substrate 1 including gate electrode 11. An anisotropic etching process may be performed with respect to the resultant structure, which may form sidewall insulating layers 14 at both sides of gate insulating layer 12 and gate electrode 11. High-density N type impurity area 15 may be formed at N type well 16 of both sides of gate electrode 11, for example by using gate electrode 11 and sidewall insulating layers 14 as a mask.

Thereafter, although not illustrated in the drawings, a protection layer may be formed, and a metal interconnection may be formed on the protection layer.

A method for manufacturing a related art MOS varactor may have various problems. For example, if the MOS varactor operates in an inversion area, it may be necessary to maintain the surface density of the N type well in a low level because the surface density of the N type well may exert an influence upon the capacitance.

However, as described above, since ions may be implanted onto the surface of the semiconductor substrate to adjust a threshold voltage, the minimum value of a capacitor may be restricted, so a tuning range may be lowered.

### SUMMARY

Embodiments relate to a method for manufacturing a semiconductor device. Embodiments relate to a MOS varactor and a method for manufacturing the same that may be capable of improving a tuning range.

Embodiments relate to a MOS varactor and a method for manufacturing the same, in which an ion implantation process for adjusting a threshold voltage may be omitted so as to lower the surface density of an N type well, which may expand a tuning range.

In embodiments, a MOS varactor may include a semiconductor substrate having an active area and a field area, in which an isolation layer may be formed on the field area, an N type well formed at the active area of the semiconductor substrate, a gate insulating layer and a gate electrode formed at an upper side of the N type well, and an N type impurity area formed in the N type well at both sides of the gate electrode.

In embodiments, a method for manufacturing a MOS varactor may include forming an isolation layer in a field area on a semiconductor substrate by defining an active area and the field area, implanting punch stop ions into the active area in the semiconductor substrate such that surface density of the active area may be maintained in a range of 1016 atoms/cm3 to 1017 atoms/cm3, implanting channel stop ions into the active area in the semiconductor substrate, forming an N type well by implanting N type well ions into the active area of the semiconductor substrate, forming a gate insulating layer and a gate electrode on the N type well, and forming an N type impurity area in the N type well at both sides of the gate electrode.

### BRIEF DESCRIPTION OF THE DRAWINGS

FIGS. 1A to 1J are example drawings illustrating a related art MOS varactor;

FIGS. 2A to 2I are example sectional views illustrating a MOS varactor according to embodiments; and

FIG. 3 is an example graph showing a capacitance between a related art MOS varactor and a MOS varactor according to embodiments.

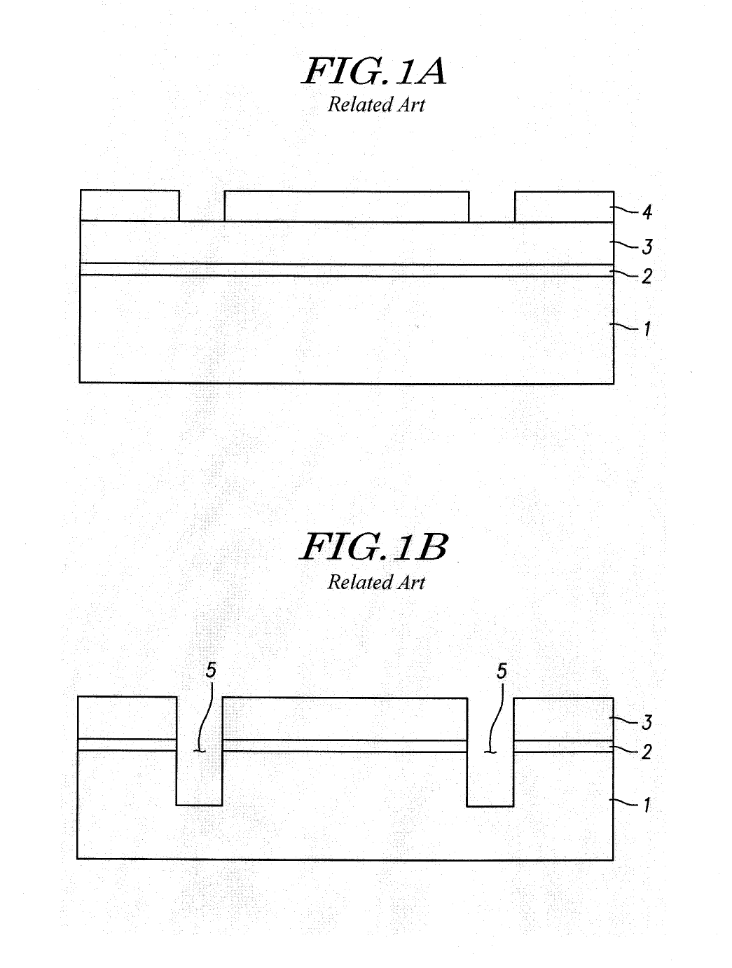

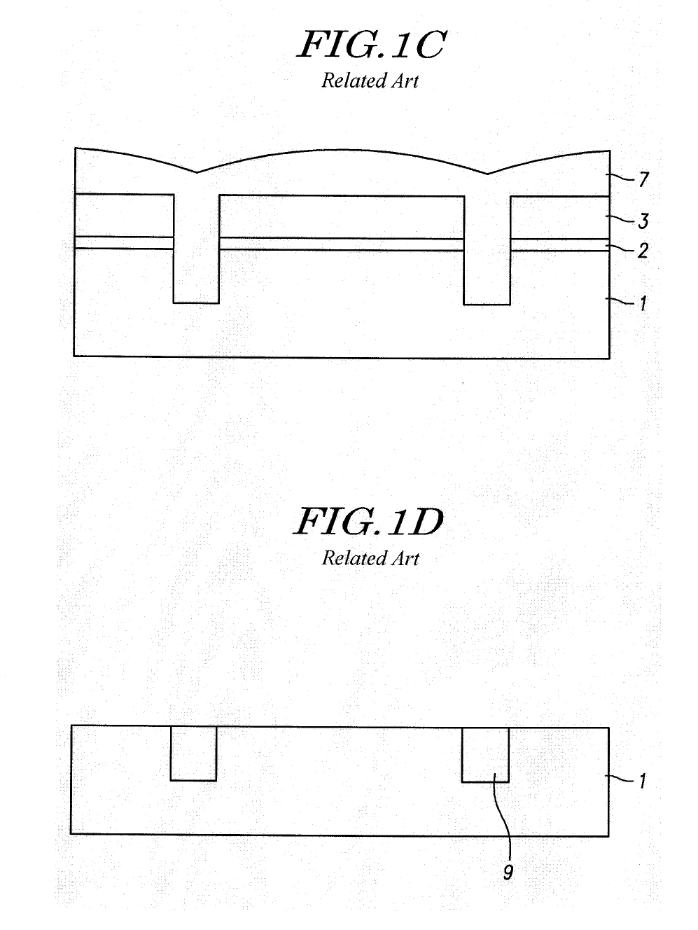

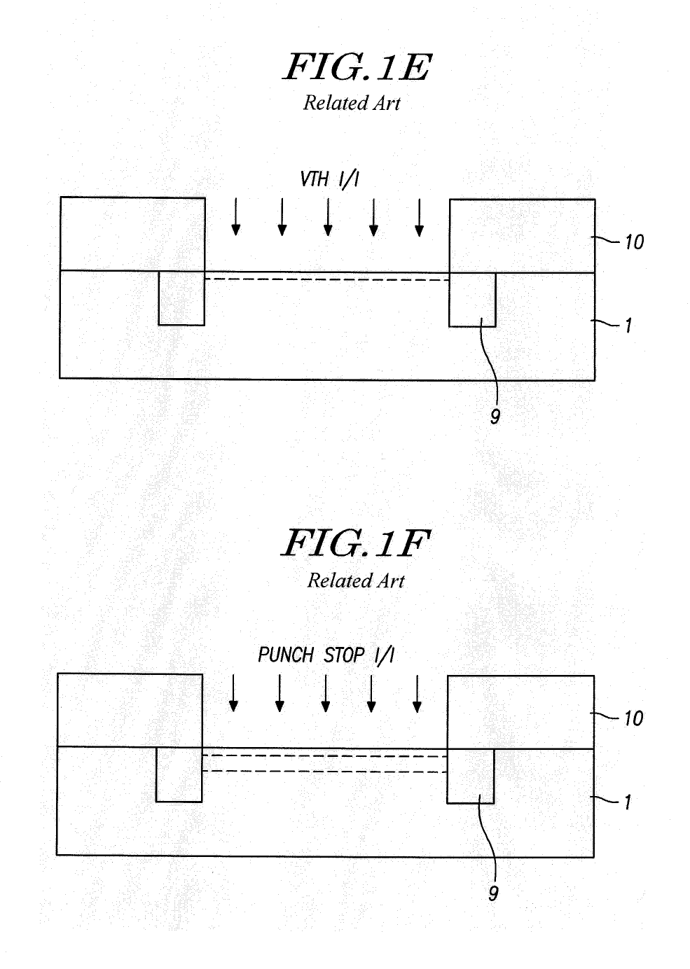

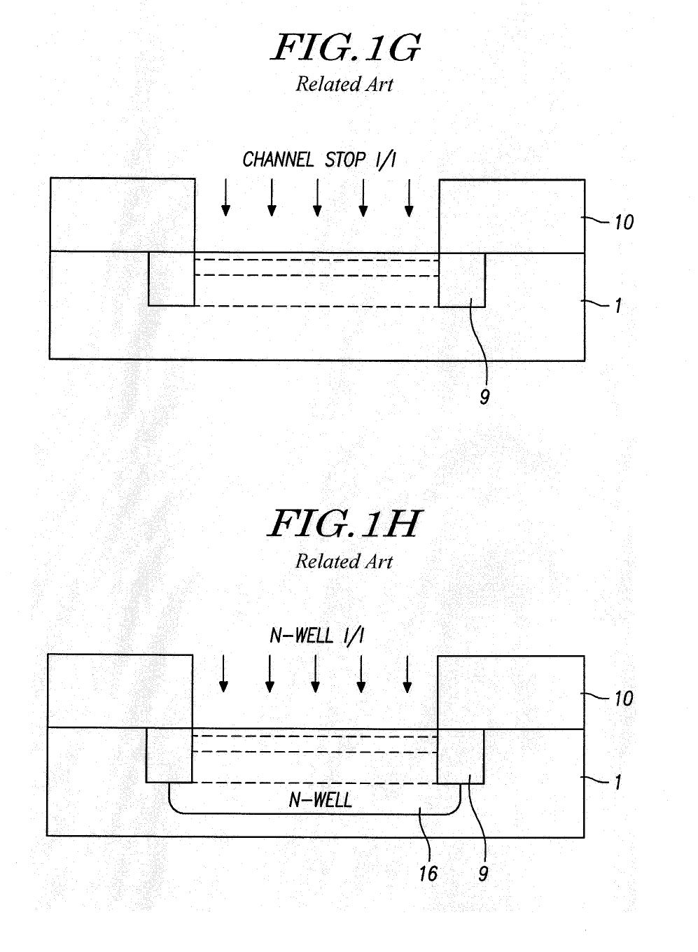

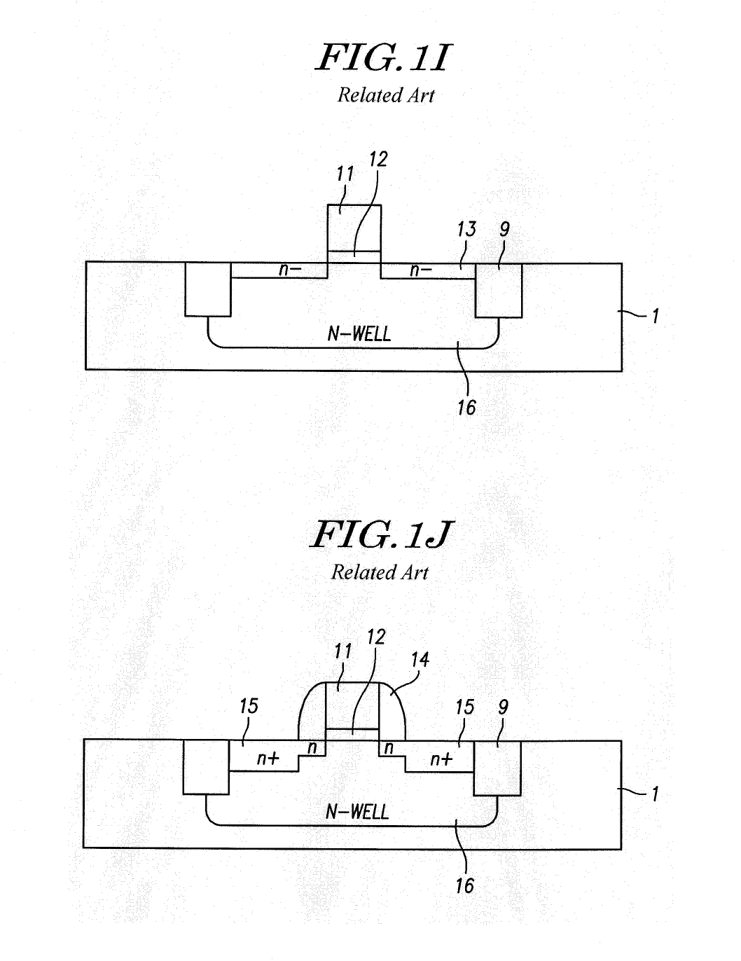

### DETAILED DESCRIPTION OF EMBODIMENTS

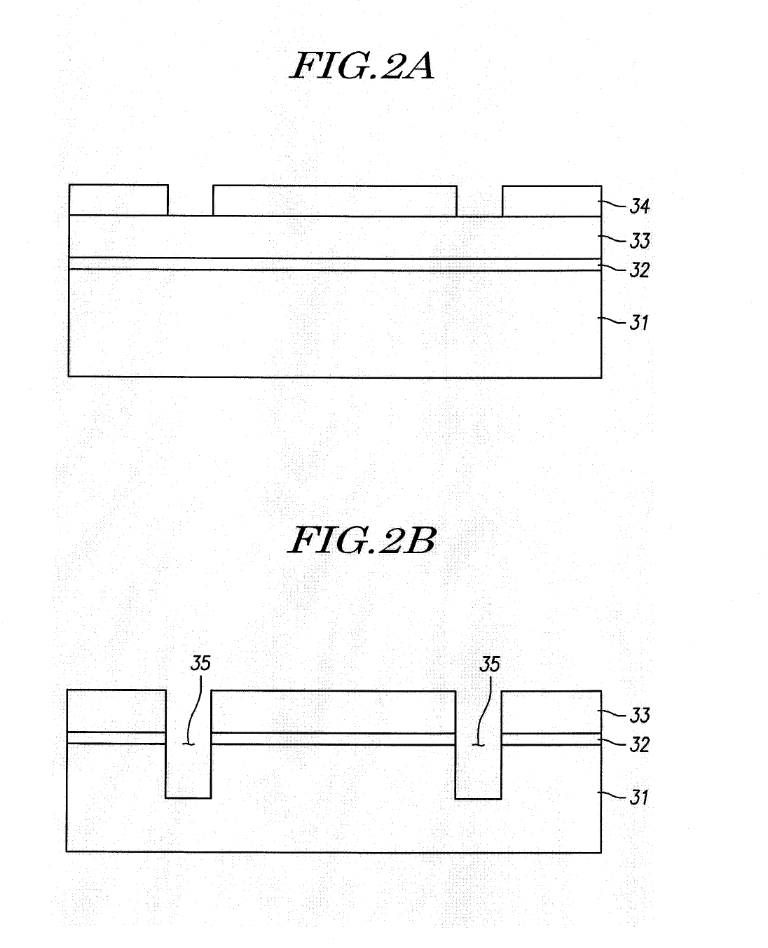

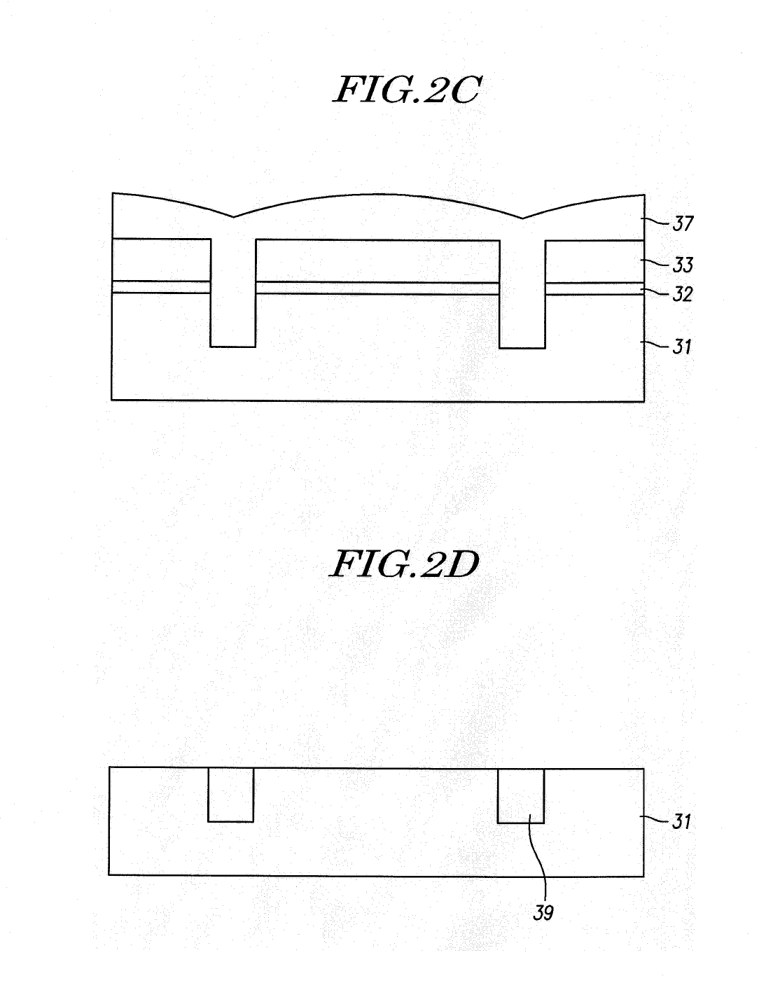

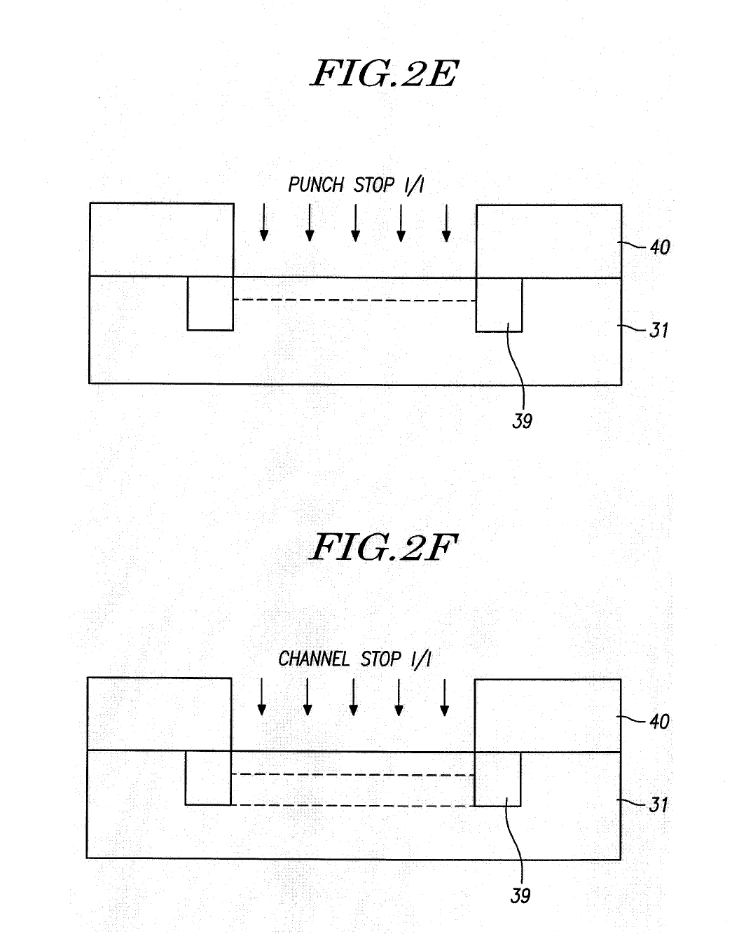

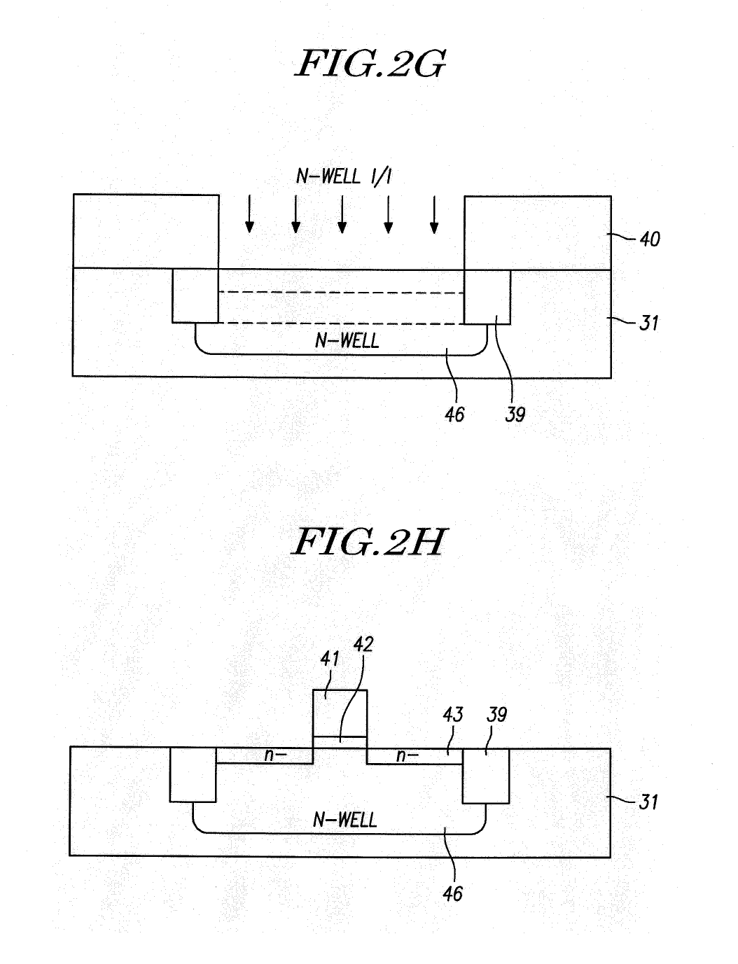

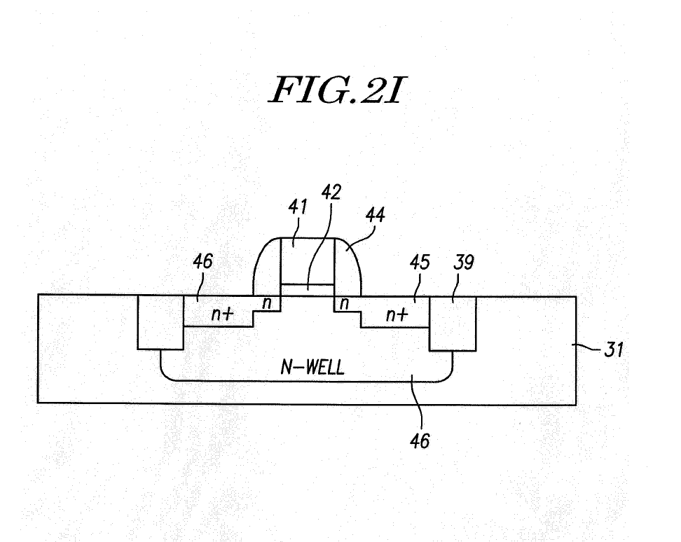

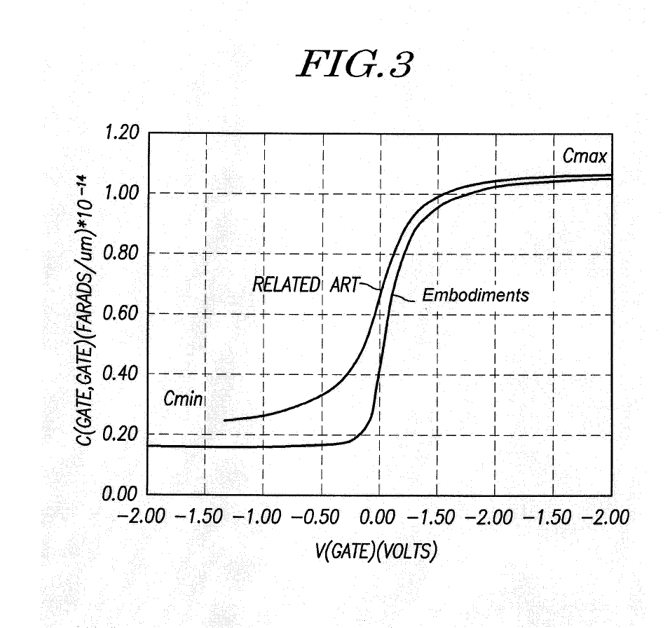

Referring to FIG. 2A, pad oxide layer (SiO₂) 32 may be formed on semiconductor substrate 31, and nitride layer (SiN) 33 may be deposited on pad oxide layer 32. Then, photoresist layer 34 may be formed on nitride layer 33, and an exposure and development process may be performed with respect to the resultant structure, for example by using a mask defining an active area and a field area. This may selectively remove photoresist layer 34 of the field area.

Referring to FIG. 2B, nitride layer 33, pad oxide layer 32, and semiconductor substrate 31 in the field area may be etched to a prescribed depth, for example by using patterned photoresist layer 34 as a mask, thereby forming trench 35. Thereafter, photoresist layer 34 may be removed.

Referring to FIG. 2C, insulating layer 37, for example such as an O₃ TEOS oxide layer, may be deposited on a surface (for example, the entire surface) of semiconductor substrate 31 formed with trench 35 such that trench 35 is filled with insulating layer 37.

Referring to FIG. 2D, insulating layer 37, nitride layer 33, and pad oxide layer 32 may be removed, for example through a chemical mechanical polishing (CMP) process. A surface of semiconductor substrate 31 may thereby be exposed. Insulating layer 37 may remain in trench 35 thereby forming isolation layer 39.

Referring to FIG. 2E, photoresist layer 40 may be deposited on a surface (for example, the entire surface) of semiconductor substrate 31 formed with isolation layer 39. Photoresist layer 40 may be patterned through an exposure and development process such that an area for the formation of a varactor may be exposed. In addition, a punch stop ion implantation process may be performed.

Through the punch stop ion implantation process, phosphorus (P) ions may be implanted with energy of 200 KeV or less. A density of ion implantation is about 10¹³ atoms/cm².

Referring to FIG. 2F, if the punch stop ion implantation process is completed, a channel stop ion implantation process may be performed. The channel stop ions may be implanted to a depth corresponding to the depth of the isolation layer. For example, phosphorus (P) ions may be implanted with energy of 300 KeV or less. A density of ions in the channel punch stop ion implantation process may be identical to a density of ions in the punch stop ion implantation process.

Referring to FIG. 2G, if the channel stop ion implantation process is completed, an N type well ion implantation process may be performed. The N type well ion implantation may be deeper than the channel stop ion implantation. For example, phosphorus (P) ions may be implanted with energy of 500 KeV or less. A density of ions in the N type well ion implantation process may be identical to a density of ions in the punch stop ion implantation process. A diffusion process may also be performed, thereby forming N type well 46.

Referring to FIG. 2H, photoresist layer 40 may be removed. Gate insulating layer 42 and gate electrode 41 may be formed on N type well 46, and low-density N type impurity areas 43 may be formed in N type well 46 at both sides of gate electrode 41, for example by using gate electrode 41 as a mask.

Referring to FIG. 2I, an insulating layer may be deposited on a surface (for example, the entire surface) of semiconductor substrate 31 including gate electrode 41. An anisotropic etching process may be performed with respect to the resultant structure, and may form sidewall insulating layers 44 at both sides of gate insulating layer 42 and gate electrode 41. High-density N type impurity area 45 may be formed at N type well 16 of both sides of gate electrode 11, for example by using gate electrode 41 and sidewall insulating layers 44 as a mask.

In embodiments, since ion implantation for adjusting a threshold voltage may not be performed, a doping density of the semiconductor substrate may be maintained in the range of 10¹⁶ atoms/cm³ to 10¹⁷ atoms/cm³.

Thereafter, although not illustrated in the drawings, a protection layer may be formed, and a metal interconnection may be formed.

According to embodiments, a method for manufacturing a MOS varactor may have various advantages. For example, a tuning range may be increased.

FIG. 3 is an example graph illustrating a comparison of the maximum capacitance (Cmas) and the minimum capacitance (Cmin) of a MOS varactor capacitor according to embodiments and according to the related art.

According to embodiments, since an ion implantation process for adjusting a threshold voltage may not be performed with respect to the surface of the semiconductor substrate, a density of the surface of the semiconductor substrate may be maintained in the range of about 10¹⁶ atoms/cm³ to 10 atoms/cm³. Accordingly, referring to FIG. 3, when a negative voltage is applied to the gate electrode, an inversion area may be activated in an interfacial surface between the semiconductor substrate and the gate insulation layer corresponding to the gate electrode, so the minimum capacitance (Cmin) of a capacitor may be more lowered. Therefore, the tuning range may be increased.

It will be apparent to those skilled in the art that various modifications and variations can be made to embodiments. Thus, it is intended that embodiments cover modifications and variations thereof within the scope of the appended claims. It is also understood that when a layer is referred to as being “on” or “over” another layer or substrate, it can be directly on the other layer or substrate, or intervening layers may also be present.

What is claimed is:

1. A device, comprising:
a semiconductor substrate having an active area and a field area, in which an isolation layer is formed on the field area to define the active area; and
an N type well formed in the active area of the semiconductor substrate,
wherein an impurity surface density of the N type well is in a range of 10¹⁶ atoms/cm³ to 10¹⁷ atoms/cm³.

2. The device of claim 1, further comprising:
a gate insulating layer and a gate electrode formed over the N type well; and
an N type impurity area formed in the N type well at sides of the gate electrode.

3. The device of claim 1, wherein forming the N type well comprises:
implanting punch stop ions into the active area in the semiconductor substrate with an energy of 200 KeV or less and a density of ion implantation of approximately 10¹³ atoms/cm²;
implanting channel stop ions into the active area in the semiconductor substrate with an energy of 300 KeV or less and a density of ion implantation of approximately 10¹³ atoms/cm²; and
implanting N type well ions into the active area of the semiconductor substrate with an energy of 500 KeV or less and a density of ion implantation of approximately 10¹³ atoms/cm².

4. The device of claim 3, wherein implanting the punch stop ions into the active area in the semiconductor substrate is the first ion implantation performed on the active area after preparing the semiconductor substrate with the isolation layer.

5. A method, comprising:
forming an isolation layer in a field area on a semiconductor substrate by defining an active area and a field area;
implanting punch stop ions into the active area in the semiconductor substrate such that surface density of the active area is maintained in a range of 10¹⁶ atoms/cm³ to 10¹⁷ atoms/cm³;
implanting channel stop ions into the active area in the semiconductor substrate; and
forming an N type well by implanting N type well ions into the active area of the semiconductor substrate.

6. The method of claim 5, further comprising:
forming a gate insulating layer and a gate electrode over the N type well; and
forming an N type impurity area in the N type well at both sides of the gate electrode.

7. The method of claim 5, wherein the punch stop ion implantation is performed by implanting phosphorus ions having density of 10¹³ atoms/cm² with energy of 200 KeV or less.

8. The method of claim 5, wherein the channel stop ion implantation is performed by implanting phosphorus ions having density of 10¹³ atoms/cm² with energy of 300 KeV or less.

9. The method of claim 5, wherein the N type well ions implantation is performed by implanting phosphorus ions having density of 10¹³ atoms/cm² with energy of 500 KeV or less.

10. The method of claim 5, wherein implanting punch stop ions into the active area in the semiconductor substrate is the first ion implantation performed in the active area subsequent to forming the isolation layer.

11. A method, comprising:
forming an isolation layer in a field area on a semiconductor substrate by defining an active area and a field area;
implanting punch stop ions into the active area in the semiconductor substrate with an energy of 200 KeV or less and a density of ion implantation of approximately 10¹³ atoms/cm²;
implanting channel stop ions into the active area in the semiconductor substrate with an energy of 300 KeV or less and a density of ion implantation of approximately 10¹³ atoms/cm²; and
implanting N type well ions into the active area of the semiconductor substrate with an energy of 500 KeV or less and a density of ion implantation of approximately 10¹³ atoms/cm².

12. The method of claim 11, wherein an impurity surface density of the N type well is formed to be in a range of 10¹⁶ atoms/cm³ to 10¹⁷ atoms/cm³.

13. The method of claim 12, wherein implanting the punch stop ions into the active area in the semiconductor substrate is the first ion implantation performed in the active area after forming the isolation layer.

14. The method of claim 12, wherein each of the punch stop ions, the channel stop ions in the N type well ions comprises phosphorus ions.
